(19) United States
(12) Patent Application Publication
(10) Pub. No.: US 2014/0049102 A1
(43) Pub. Date: Feb. 20, 2014

(54) ELECTRONIC CONTROL UNIT ASSEMBLY AND VEHICLE COMPRISING THE SAME

(71) Applicants: Xiuping Li, Suzhou (CN); Jingyu Pang, Suzhou (CN); Stephen Tian, Suzhou (CN)

(72) Inventors: Xiuping Li, Suzhou (CN); Jingyu Pang, Suzhou (CN); Stephen Tian, Suzhou (CN)

(73) Assignee: BOSCH AUTOMOTIVE PRODUCTS (SUZHOU) CO., LTD., Suzhou, Jiangsu (CN)

(21) Appl. No.: 14/114,527

(22) PCT Filed: Apr. 28, 2012
(86) PCT No.: PCT/CN2012/074893

§ 371 Date: Oct. 28, 2013

(30) Foreign Application Priority Data
Apr. 29, 2011 (CN) 201110115836.2

(51) Int. Cl. H05K 5/03

(52) U.S. Cl. CPC H05K 5/03
USPC 307/9.1; 361/820

(57) ABSTRACT

An electronic control unit (ECU) assembly is provided, which includes a covering part, one or more metal oxide semiconductor field effect transistors (MOSFETs) (1), a substrate and an ECU main body. The covering part includes a lid element (3) having latch parts (6); the lid element (3) is secured onto the ECU main body via the latch parts (6); and the MOSFETs (1) are arranged between the lid element (3) and the substrate (9). The covering part further includes a middle element, which is in tight contact with and is elastically pressed against the MOSFETs (1), such that the MOSFETs (1) are brought into tight contact with the substrate. Thereby, the MOSFETs (1) are reliably fixed in the ECU assembly. A vehicle including the ECU assembly is also provided.

### TECHNICAL FIELD OF THE INVENTION

The present invention relates to an electronic control unit assembly including one or more metallic oxide semiconductor field effect transistors, and relates to a vehicle including such an electronic control unit assembly.

### BACKGROUND ART OF THE INVENTION

An electronic control unit (ECU), as a known control unit, has been widely used in the various vehicles, and is capable of carrying out the precise and complex control for the respective components of the vehicles. The ECU can receive signals from the various sensors, and output, based on a certain strategy, control commands to, for example, the engine system, steering system, braking system and the like in the vehicle, so as to control the systems. In the current ECU assembly, metallic oxide semiconductor field effect transistors (MOSFETs) usually are provided for controlling the switching on and off of the current and amplifying the power.

In the known MOSFET, at one end thereof, the pin extending outwards from the MOSFET is welded to a printed circuit board (PCB), and at the other end thereof, the plate extending outwards from the MOSFET is provided with through holes, into which bolts are inserted, whereby the MOSFET is secured to the ECU substrate.

For example, in the published document WO 2005/013658 A1, the power element MOSFET is fixed to the heat sink via a pressure adjusting screw, a heat radiation sheet and an L-shaped fitting. Another example, the patent application JP 8-204359A discloses a different MOSFET mounting manners, wherein the mounting ends of two side-by-side MOSFETs are provided with an assembling clamp plate, and one bolt passes through the assembling clamp plate to clamp and fix the MOSFETs. Further by making reference to patent application JP 2004-335959 A, according to the disclosure thereof, the bottom mounting surface of the MOSFET is arranged at a certain angle to the associated circuit board, and the MOSFET is also fastened in the mounting manner of passing the screw through mounting end thereof.

The above-mentioned MOSFET mounting manners have many disadvantages.

Firstly, the fixing points of the bolt all are located on the mounting end at one side of the MOSFET, that is to say, the MOSFET force-bearing point is not at the center of the MOSFET. Thus, under the screwed state of the bolt, the acting force can not be evenly distributed on the contacting surfaces between the MOSFET and the ECU substrate. Therefore, between the contacting surfaces, a gap will be inevitably generated on some parts of the contact surfaces. That is to say, the two surfaces are not evenly bonded to each other, and the heat transfer between the MOSFET and the substrate will be influenced unfavorably.

Secondly, during the process of securing the bolt to the ECU substrate, an extra force will be applied to a welding spot at the MOSFET pin. Moreover, since the MOSFET welding spot and the mounting end usually are located on the opposite sides, the acting force received by the welding spot will be enlarged further, and this may damage the welding spot.

Finally, during the tightening process of the bolt, due to the friction contact between the internal and external threads, small metal debris may be generated from the external thread of the bolt or the internal thread of the substrate. When the metal debris fall into the ECU, the PCB short circuit may be caused, and then resulting in serious damage of the ECU.

### SUMMARY OF THE INVENTION

An object of the present invention is to provide an electronic control unit assembly, which has the favorable heat dissipation capacity and is capable of achieving the stable installation of metallic oxide semiconductor field effect transistors in the electronic control unit assembly, and which thus has the high reliability and long service life. According to the electronic control unit assembly of the invention, the metallic oxide semiconductor field effect transistors are installed without the aid of bolts and washers, but are secured to a substrate of an electronic control unit by means of a lid element of the electronic control unit and a gasket. Thereby, the above disadvantages can be removed.

According to one aspect of the present invention, an electronic control unit (ECU) assembly is provided, which comprises a covering part, one or more metallic oxide semiconductor field effect transistors (MOSFETs), a substrate and an electronic control unit main body, wherein the covering part comprises a lid element having latch parts, the lid element is secured onto the electronic control unit main body via the latch parts, the metallic oxide semiconductor field effect transistor is arranged between the lid element and the substrate, and wherein the covering part further comprises a middle element, which is in tight contact with and is elastically pressed against the metallic oxide semiconductor field effect transistor such that the metallic oxide semiconductor field effect transistor is brought into tight contact with the substrate.

Obviously, the middle element may be a part formed in the lid element, or a separate component of the covering part. Moreover, one middle element may be brought into tight contact with a plurality of metallic oxide semiconductor field effect transistors or with one metallic oxide semiconductor field effect transistor.

According to one preferred embodiment of the invention, the middle element is one or more gaskets formed by elastomers. Such gaskets can continuously exert the elastic counterforce on the metallic oxide semiconductor field effect transistor, so as to ensure the reliable fixation.

According to another preferred embodiment of the invention, the covering part further comprises a sealing pad, which is integrally formed with the gasket. Whereby, the technical solutions defined in the present invention can be arrived at only by making the small changes to the existing lid element and the sealing pad.

According to another preferred embodiment of the invention, the lid element is provided with projecting parts at inner side thereof, which tightly abut against the gaskets such that the gaskets undergo elastic deformation. Preferably, the shape, size and position of the projecting parts are set in such a way that when the gaskets undergo the elastic deformation, the action point of resultant force between the metallic oxide semiconductor field effect transistor and the electronic control unit substrate is at a central position of the lower surface of the metallic oxide semiconductor field effect transistor.

According to another preferred embodiment of the invention, the projecting parts are in the shape of a hollow cylinder, a column, a crisscross or a star. These projecting parts can ensure that the metallic oxide semiconductor field effect transistor is under even pressure so as to tightly bonded to the electronic control unit substrate (or heat sink), thereby achieving the better heat transfer.

According to another preferred embodiment of the invention, the latch parts are arranged around the lid element, and are snap-engaged with protrusions of the electronic control unit main body. Of course, it can be understood that other types of locking connection modes may be used between the lid element and the electronic control unit main body.

According to another preferred embodiment of the invention, the sealing pad comprises a frame part, which is tightly clamped between the lid element and the substrate.

According to another preferred embodiment of the invention, the gasket is made of rubber.

According to another preferred embodiment of the invention, the gasket is separated from the sealing pad. In this embodiment, one or more sealing pads can be provided in a simple manner and at low cost.

According to another aspect of the present invention, a vehicle is provided, which includes the above electronic control unit assembly.

The electronic control unit assembly according to the present invention can bring the even contact between the metallic oxide semiconductor field effect transistor and the substrate, thereby achieving the better heat dissipation. Since the operation of tightening the bolt is omitted, the welding spot of the pin of the metallic oxide semiconductor field effect transistor will not be suffered from the extra acting force any more. Moreover, the possibility of generating the metal debris is eliminated, and this greatly enhances the reliability of the metallic oxide semiconductor field effect transistor, thereby making the electronic control unit assembly to have the high reliability and long service life.

### BRIEF DESCRIPTION OF THE DRAWINGS

Hereinafter the preferred embodiments of the invention are described with reference to the drawings, wherein:

FIG. 1 as a perspective view schematically shows a known typical MOSFET;

FIG. 2 as a perspective view shows a lid element of the ECU assembly of the present invention schematically from the outer side;

FIG. 3 as a perspective view shows the lid element in FIG. 2 schematically from the inner side, wherein FIG. 3 is turned horizontally by 180° relative to FIG. 2;

FIG. 4 as a plan view shows the lid element in FIG. 3 schematically from the inner side;

FIG. 5 as a sectional view shows one cross section of the lid element in FIG. 2, which is cut away along the line E-E in FIG. 4;

FIG. 6 as a partially enlarged sectional view shows the installed ECU assembly of the present invention under the assembling state;

FIG. 7 as a perspective view schematically shows a sealing pad of the present invention; and

FIG. 8 as a perspective view schematically shows the sealing pad in FIG. 7, which is turned horizontally by 180° relative to FIG. 7.

### DETAILED DESCRIPTION OF THE INVENTION

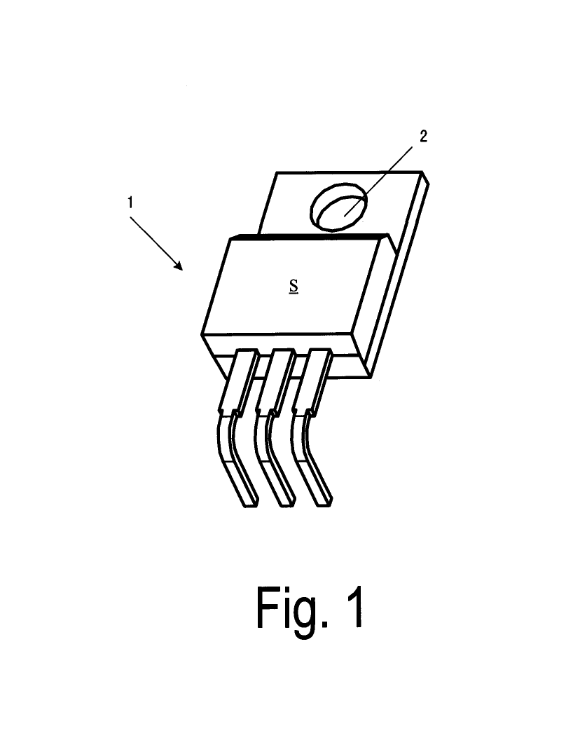

FIG. 1 shows one known typical MOSFET schematically, which is designated by reference sign “1”. The MOSFET 1 at one end is provided with three pins to be welded to the PCB, and at the other end with a through hole 2. In the known ECU assembly, the MOSFET 1 is mounted into the ECU assembly by means of the threaded connection with the ECU substrate by passing the bolt through the washer and through the through hole 2.

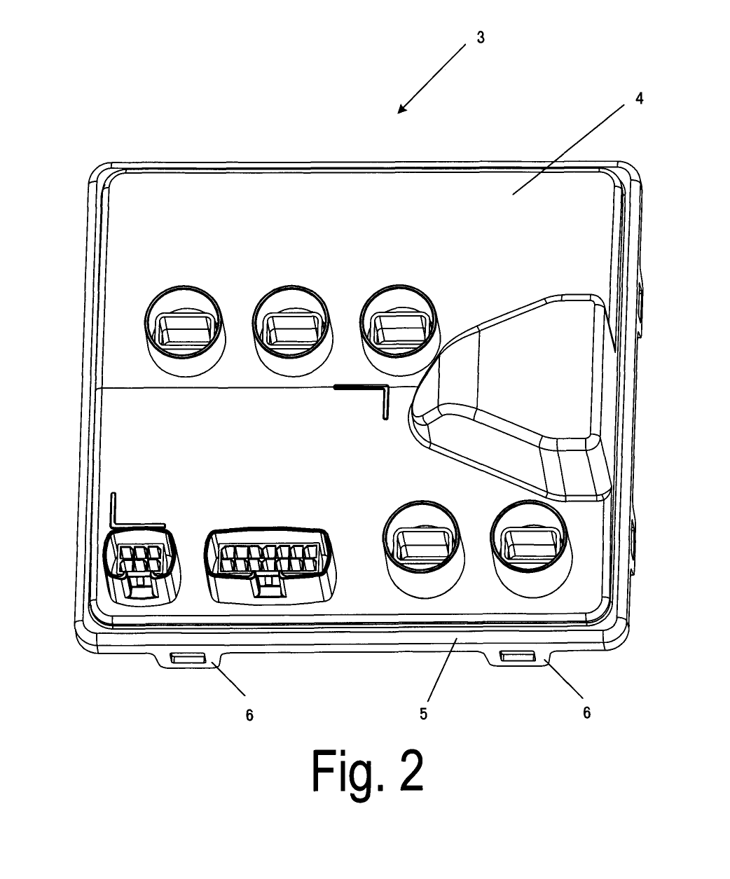

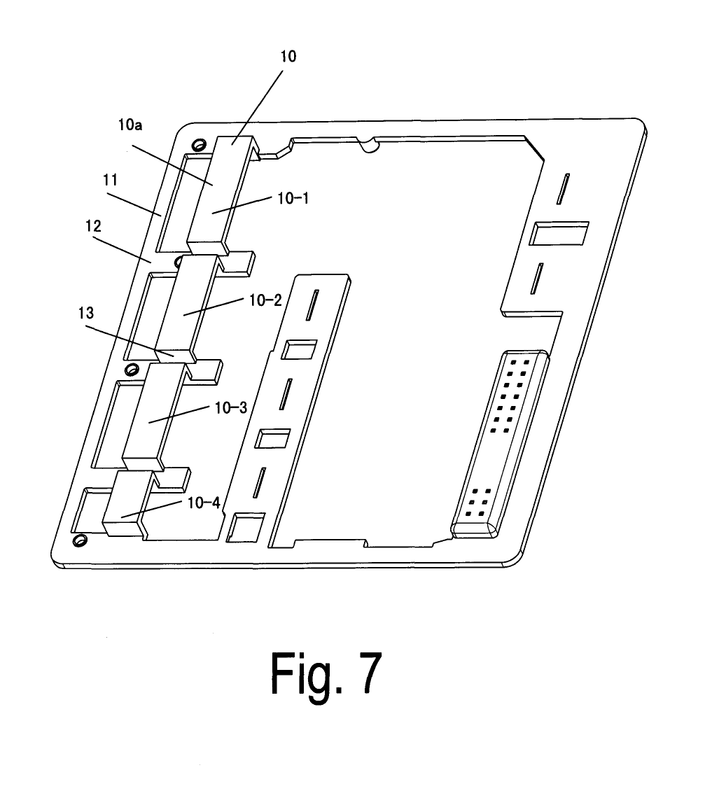

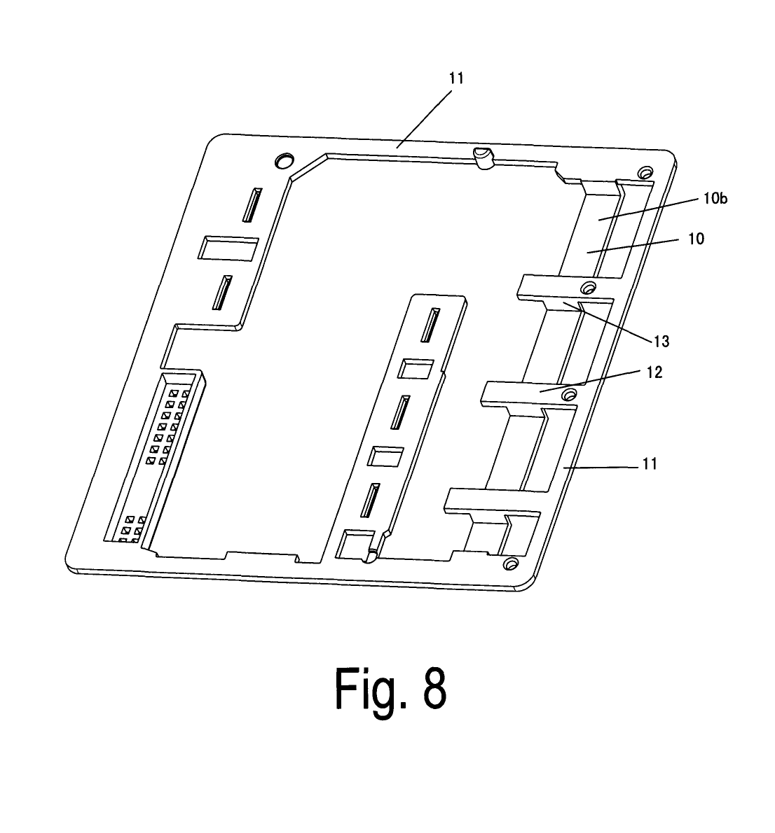

According to one embodiment of the invention, the ECU assembly has a covering part, which comprises a lid element 3 (see FIGS. 2-4) and a sealing pad (see FIGS. 7-8).

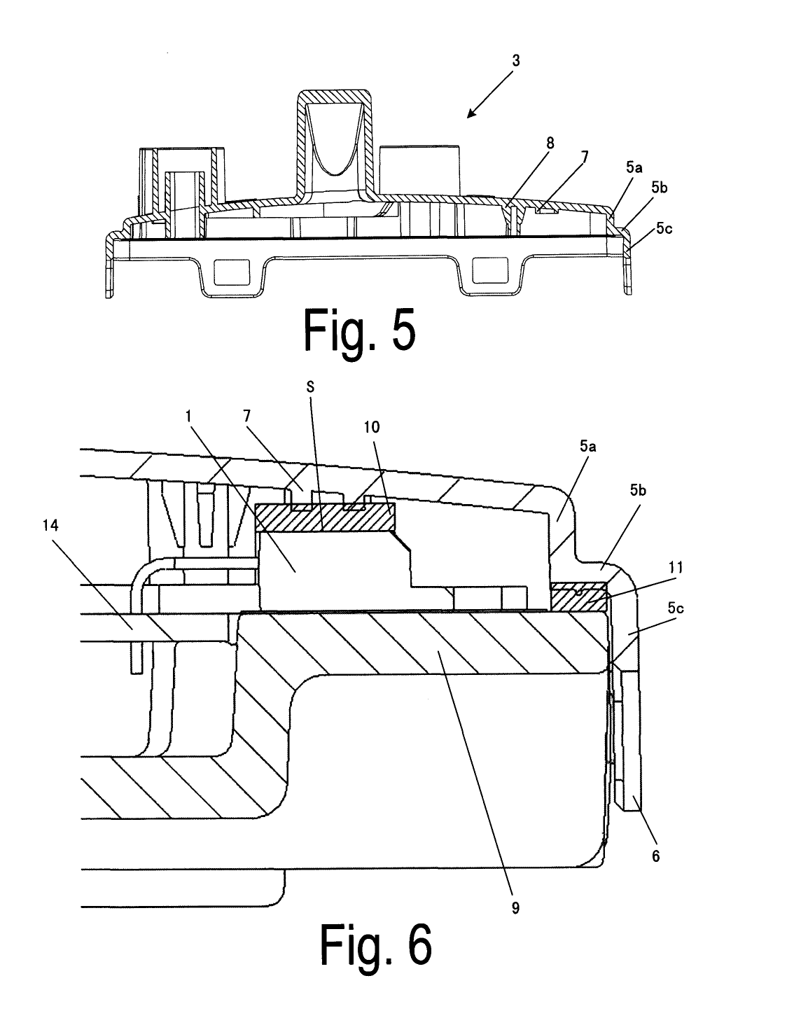

FIGS. 2-4 show the complete lid element 3 comprising a main body 4 and a lateral part 5. The main body 4 is slightly arched outwards (as shown in the sectional view of FIG. 5). Referring to FIG. 2, a plurality of connecting parts and socket parts are provided at the outer side of the main body 4 for inserting the connecting terminals of the various cables therein, thereby achieving the communication of data and/or supply of the power supply.

Referring to FIG. 5, the lateral part 5 comprises of a first lateral part 5a, a step 5b and a second lateral part 5c, which extend in order from the circumferential edge of the main body 4, and the first lateral part 5a, the step 5b and the second lateral part 5c encircle the periphery of the main body 4. The first lateral part 5a extends in a suspended manner from the circumferential edge of the main body 4 that is generally rectangular, and the step 5b is perpendicular to the first lateral part 5a and extends outwards from an end of the first lateral part 5a. The second lateral part 5c is perpendicular to the step 5b and extends from an end of the step 5b, and the extending direction thereof is the same as and parallel to the extending direction of the first lateral part 5a. At each of the four sides of the main body 4, two latch parts 6 with recesses or through holes are arranged on the second lateral part 5c (refer to FIG. 2), and the latch parts 6 are adapted to be slightly inclined outwards when subjected to an outwards-directed acting force, and to be engaged with protrusions at the corresponding places on the outer circumferential wall of the ECU main body, thereby firmly locking the lid element 3 to the ECU main body.

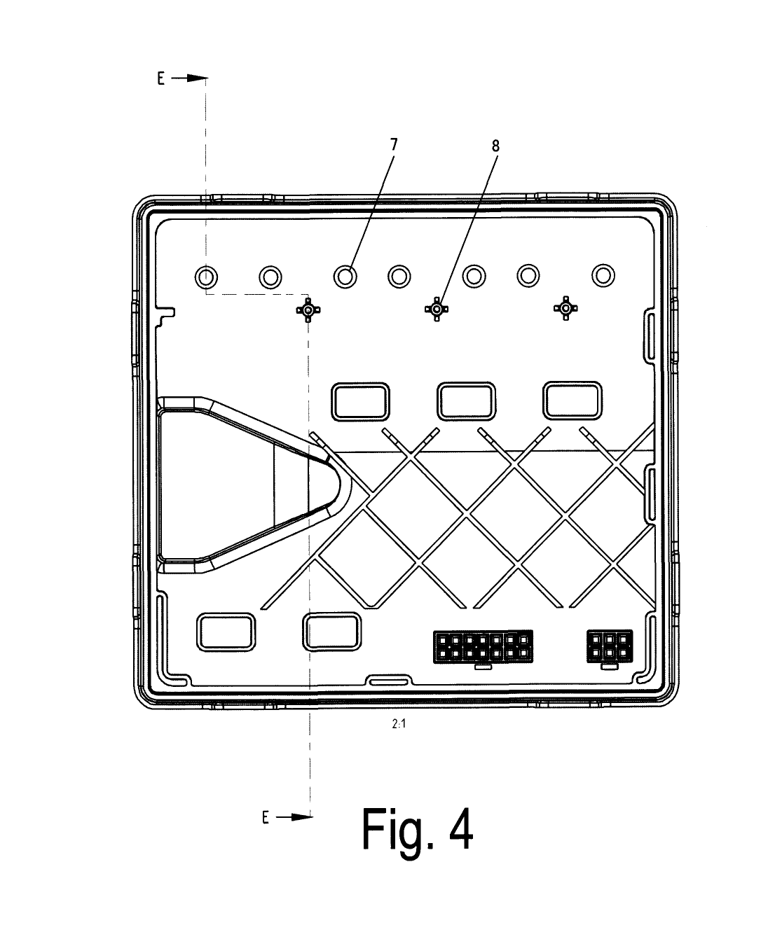

In that embodiment, the main body 4 is slightly arched outwards, and as viewed in the top view such as shown by FIG. 4, the main body 4 is generally rectangular. However, it can be understood that the main body 4 may have other proper shapes and structures. For example, the main body 4 may have a flat shape, and the circumferential edge thereof may be a circle, a polygon in addition to quadrangle, and the like.

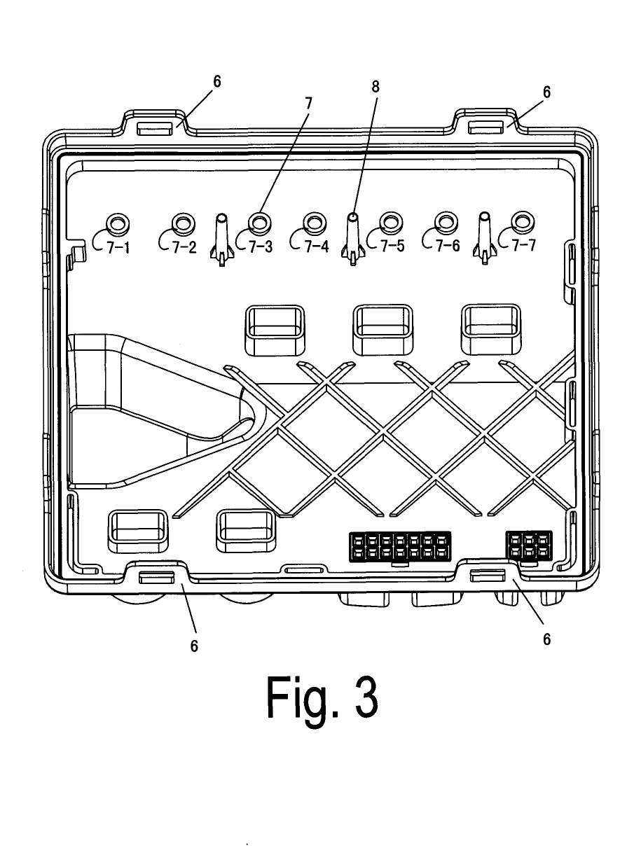

Referring to FIGS. 3 and 4, the inside structures of the lid element 3 are shown therein. At the inner side of the main body 4, a plurality of projecting parts 7 and a plurality of projecting nails 8 are provided, which extend inwards from the inner wall of the main body 4, and the extending distance of the projecting parts 7 from the inner wall of the main body 4 is less than the extending distance of the projecting nails 8 from the inner wall of the main body 4. In the embodiment, the lid element 3 has seven generally cylindrical projecting parts 7, and moreover seven MOSFETs 1 can be installed in the ECU assembly. After the lid element 3 and the ECU are installed and connected well, each projecting part 7 just is located above the general central position of the top surface S of one corresponding MOSFET 1, and thus the MOSFET 1 is pressed. In this way, the MOSFET 1 is secured, and the bolt necessary in the prior art is omitted. In addition, under this installing state, the projecting nails 8 are pressed against the PCB, so as to keep the PCB in the ECU assembly in place.

Referring to FIG. 6, a partial sectional view shows the ECU assembly of the present invention under the assembling state. In FIG. 6, the pin at one end of the MOSFET 1 is welded to the PCB 14, and no bolt is provided at the other end of the MOSFET. The top surface S of the MOSFET 1 is covered with a gasket 10. Under the assembling state shown by FIG. 6, the latch parts 6 on the lateral part 5 of the lid element 3 are engaged with the protrusions at the outer side of the ECU main body, and moreover the projecting part 7 is tightly pressed to the gasket 10 and the MOSFET 1, and the projecting nail 8 is pressed against the PCB 14 (refer to FIG. 6). Hereby, the MOSFET 1 is firmly clamped between the lid element 3 and the ECU substrate 9.

The gasket 10 is made from a material that undergoes the elastic deformation when being pressed, such as elastomer, and when contacting the projecting part 7, the area of the upper surface 10a of the gasket 10 is greater than the contacting area with the projecting part 7. Thereby, under the assembling state, the projecting part 7 of the lid element 3 protrudes partially into the upper surface 10a of the gasket 10, and tightly presses the gasket 10 to undergo the elastic deformation. At the opposite side of the gasket 10, the lower surface 10b of the gasket 10 is brought into contact with the top surface S of the MOSFET 1. The size of the gasket 10 is set in such a way that the area of the upper surface 10a thereof is at least equal to the area of the contacting surface where the projecting part 7 contacts the gasket 10, and that the area of the lower surface 10b thereof is at least equal to the area of the top surface S of the MOSFET 1. The thickness of the gasket 10 and the size of the lateral part 5 of the lid element 3 are selected such that when the latch parts 6 are engaged with the protrusions at the outer side of the ECU main body, the gasket 10 is pressed by the projecting part 7 and generates the elastic deformation.

Under the assembling state, the load is sufficiently evenly distributed on the top surface S of the MOSFET 1 by means of the above-mentioned gasket 10, and at the same time the exterior vibration transmitted by the lid element 3 is absorbed via the deformation of the gasket 10, so as to effectively protect the MOSFET 1. In addition, since the elastic counterforce that is inevitably generated when the gasket 10 elastically deforms exist always, the lid element 3, the gasket 10, the MOSFET 1 and the substrate 9 are always tightly bonded to each other. That is, the reliable and stable installation of the MOSFET 1 can be ensured.

The gasket 10 according to the present invention can be formed in a very simple manner. For example, one simple independent rectangular gasket 10 may be provided for each MOSFET, and the gasket 10 has a shape corresponding to the top surface S of the relevant MOSFET. Preferably, as shown in FIGS. 7 and 8, the gasket 10 is combined into the existing sealing pad of the ECU assembly, and moreover one gasket 10 may be bonded to one or more MOSFETs.

Referring to FIGS. 7 and 8, the sealing pad in the ECU assembly is schematically shown therein, which usually has the function of preventing water and dust from intruding into the ECU assembly. The sealing pad comprises a frame part 11, a plurality of support bars 12 extending inwards from the frame part 11, and vertical connecting pieces 13 being perpendicular to the support bars 12 and extending from the edges thereof. Under the assembling state, the sealing pad is arranged between the lid element 3 and the ECU substrate 9 (see FIG. 6), and when the latch parts 6 are engaged with the protrusions at the outer side of the ECU main body, the frame part 11 is tightly pressed by the step 5b to cause the elastic deformation, as shown in FIG. 6.

In the present embodiment, FIGS. 7 and 8 clearly show that all the gaskets 10 are in the same plane, which is parallel to the plane where the frame part 11 is located. Each gasket 10 at both ends is connected to the edges of the support bar 12 via corresponding vertical connecting pieces 13. The respective vertical connecting pieces 13 are parallel to each other and perpendicular to the plane where the frame part 11 is located. The gaskets 10 are integrally formed with the support bars 12 and the vertical connecting pieces 13 of the sealing pad. The whole sealing pad is made from a material that can provide the elastic deformation when being pressed, such as elastomer, and especially rubber.

Referring to FIGS. 3 and 7, for the sake of convenience, each projecting part 7 and each gasket 10 are labeled by a number. At the time of installing, the projecting parts 7-1, 7-2 are pressed against the gasket 10-1; the projecting parts 7-3, 7-4 are pressed against the gasket 10-2; the projecting parts 7-5, 7-6 are pressed against the gasket 10-3; and the projecting part 7-7 is pressed against the gasket 10-4. The gaskets 10-1, 10-2, 10-3 respectively press two adjacent MOSFETs, while the gasket 10-4 presses one separate MOSFET. In this way, the lid element 3 during installing is tightly connected to the ECU main body via the latch parts 6, such that the respective projecting parts 7 press the corresponding gasket 10 and thus the gaskets 10 press the MOSFETs, thereby reliably fixing the MOSFETs in the ECU main body.

Hereinbefore, one embodiment is described in details with reference to the drawings. Based on the embodiment, the present invention can embrace the various variations.

For example, in the above embodiment, the lid element 3 has seven projecting parts 7, and the projecting parts 7 are in the shape of a hollow cylinder. However, the lid element 3 may have other projecting parts 7 in number, and the projecting parts 7 may have other proper shapes. Preferably, the structure and size of the projecting parts 7 are set favorable for the even distribution of the load on the gaskets 10, and this usually requires that the action point of resultant force of the acting forces exerted by the projecting parts 7 on the gaskets 10 (further on the MOSFET) is located at the general central position above the top surface S of the MOSFET. For example, the projecting parts 7 may be in the shape of a column, a crisscross or a star. The projecting part also may be configured as a main body having a generally columnar shape, and may have a plurality of spokewise-arranged extensions extending outwards from the main body around the main body, wherein the axial spaces between the respective extensions are equal to each other, for example, three or more such extensions may be provided. The projecting parts of such a design can have the greater contacting area on the one hand, and can enhance the structural intensity on the other hand. Alternatively, the action point where the projecting part 7 exerts a force on the gasket 10 may be offset slightly towards the end of the MOSFET having the through hole. In addition, upon the teaching of the present invention, these skilled in the art can easily conceive other proper shapes of the contacting surface.

In the above embodiment, the four gaskets 10 are integrally formed with the sealing pad. However, the gaskets also may have a structure separated from the sealing pad. Moreover, it can be assumed that any proper amount of the gaskets may be used. For example, as to the condition in the above embodiment where seven MOSFETs are provided, no more than seven gaskets or other amounts may be used. For example, seven separate gaskets may be provided such that one gasket is dedicated to one MOSFET, or all the MOSFETs may be configured to share one gasket. Alternatively, no gasket may be provided, and in this case, the projecting part 7 of the lid element 3 preferably may be made from a material that causes the elastic deformation when being stressed.

In addition, in the above embodiment, the MOSFETs are arranged on the substrate 9 in the ECU assembly. Alternatively, the MOSFETs may be arranged on a specific heat sink in the ECU assembly.

In addition, the number of the latch parts 6 of the lateral part 5 may be a number other than two, and on the other hand, the latch parts 6 may take any form convenient for locking and unlocking. For example, the latch parts 6 may be screw holes, and the lid element 3 and the ECU substrate 9 can be combined via the screws.

Usually, the present invention is adapted to being applied to the various installing circumstances of MOSFET having the lid member, especially to the ECU assemblies of the various vehicles. The vehicles may be such as ships, motorcars, motorcycles and the like.

While the foregoing is a description of the preferred embodiments of the present invention, it will be understood that these embodiments are provided for illustrative purposes only, and the present invention is not limited to the particular embodiments described herein. Those skilled in the art can make the various modifications without departing from the scope and spirit of the invention, and such modifications all fall within the scope of protection defined by the present invention.

1. An electronic control unit assembly, comprising a covering part, one or more metallic oxide semiconductor field effect transistors (1), a substrate and an electronic control unit main body, wherein the covering part comprises a lid element (3) having latch parts (6), the lid element (3) being secured onto the electronic control unit main body via the latch parts (6), the metallic oxide semiconductor field effect transistors (1) being arranged between the lid element (3) and the substrate (9), characterized in that the covering part further comprises a middle element, which is in tight contact with and is elastically pressed against the metallic oxide semiconductor field effect transistors (1), such that the metallic oxide semiconductor field effect transistors (1) are brought into tight contact with the substrate.

2. The electronic control unit assembly according to claim 1, characterized in that the middle element is one or more gaskets (10) formed by elastomers.

3. The electronic control unit assembly according to claim 2, characterized in that the covering part further comprises a sealing pad, which is integrally formed with the one or more gaskets (10).

4. The electronic control unit assembly according to claim 2, characterized in that the lid element (3) is provided with projecting parts (7) at an inner side thereof, and the projecting parts (7) tightly abut against the gaskets (10), such that the gaskets (10) undergo elastic deformation.

5. The electronic control unit assembly according to claim 4, characterized in that the projecting parts (7) are in the shape of a hollow cylinder, a column, a crisscross or a star.

6. The electronic control unit assembly according to claim 1, characterized in that the latch parts (6) are arranged around the lid element (3), and are snap-engaged with protrusions of the electronic control unit main body.

7. The electronic control unit assembly according to claim 3, characterized in that the sealing pad comprises a frame part (11), which is tightly clamped between the lid element (3) and the substrate (9).

8. The electronic control unit assembly according to claim 2, characterized in that the gaskets are made of rubber.

9. The electronic control unit assembly according to claim 3, characterized in that the gaskets are separated from the sealing pad.

10. A vehicle, characterized in that the vehicle comprises an electronic control unit assembly according to claim 1.
